(19) United States
(12) Patent Application Publication
(10) Pub. No.: US 2025/0254853 A1
(43) Pub. Date: Aug. 7, 2025

(54) METHOD FOR MAKING 8-TRANSISTOR 2-PORT STATIC RANDOM ACCESS MEMORY

(71) Applicant: Shanghai Huali Intergrated Circuit Corporation, Shanghai (CN)

(72) Inventor: Pinhan Chen, Shanghai (CN)

(73) Assignee: Shanghai Huali Integrated Circuit Corporation, Shanghai (CN)

(21) Appl. No.: 18/810,424

(22) Filed: Aug. 20, 2024

(30) Foreign Application Priority Data
Feb. 7, 2024 (CN) 202410173963.5

(51) Int. Cl. H10B 10/00

(52) U.S. Cl. CPC H10B 10/18

(57) ABSTRACT

The present application discloses a method for making an 8-transistor 2-port static random access memory, wherein an N LDD process for 6 transistors in a chip memory area uses an N LDD mask and a P LDD mask of an original storage unit, and source and drain areas of an N transistor of a read port is opened for ion injection when LDD is performed for a logic device in a chip logic area to complete an N LDD process for the N transistor of the read port, so as to adjust a threshold voltage Vt and a source-drain breakthrough current Ids of the N transistor of the read port, thereby adjusting the read current and read speed for the read port without affecting the read/write balance for 6T SRAM inside a storage unit and without an extra mask or an increase in process steps.

### CROSS-REFERENCE TO RELATED APPLICATIONS

This application claims priority to Chinese patent application No. 202410173963.5, filed on Feb. 7, 2024, the disclosure of which is incorporated herein by reference in its entirety.

### TECHNICAL FIELD

The present application relates to semiconductor circuit design technology, and in particular, to a method for making an 8-transistor 2-port static random access memory (8T2P SRAM).

### BACKGROUND

During the past 20-30 years, due to the rapid development of microelectronics technology, a component is increasingly miniaturized, a chip density is increased, and computing performance is speeded, and, a semiconductor memory is also improved significantly. In the memory, a volatile memory includes a static random access memory (SRAM) having features of low power consumption and high performance, and a dynamic random access memory (DRAM) having features of a low cost and a large storage capacity.

A variety of memories, especially a SRAM circuit, is embedded in current SOC (system on a Chip, a system level chip) to improve system performance. Generally, the SRAM circuit is preferred as an embedded memory, since it is usually used in the L1/L2 cache (level 1/level 2 high-speed cache) in an operation chip due to its compatibility with a current CMOS process. Thus, SRAM is widely used in the function and application for digital chips.

A SRAM chip includes a storage area in which a storage unit array is formed and a logic area in which a peripheral logic device is formed.

A 8-transistor 2-port static random access memory (8T2P SRAM) circuit, shown in FIG. 1, consists of 8 transistors (Tr.) and has 2 ports. Here, 6 transistors in a memory area have the function of writing/reading, with a relatively slow operating speed due to its read/write balance, wherein n1 and n2 nodes are to store data states, when an A word line (AWL)=1 enables to turn on a third N transistor PG1 and a fourth N transistor PG2, a first bit line BL1 and a second bit line BL2 are to write or read, and the first bit line BL1 and the second bit line BL2 belong to 1 port (1 port); 2 transistors in an external logic area are provided as a read port, with a relatively rapid speed, and thus a slightly large corresponding leakage current. When a B word line BWL=1 enables to turn on a fifth N transistor RP PG of a read port, the bit line RP BL of the read port is to read data.

Referring to FIG. 2, it shows the planar layout of 8 transistors (including a first N transistor PD1, a second N transistor PD2, a third N transistor PG1, a fourth N transistor PG2, a first P transistor PU1, a second P transistor PU2, a fifth N transistor RP PG, and a sixth N transistor RP PD) of the 8-transistor 2-port static random access memory (8T2P SRAM).

The planar transistor process of a conventional 8-transistor 2-port static random access memory (8T2P SRAM) is shown in FIG. 3, where N-type lightly doped drain (N LDD) processes are performed simultaneously for six N-transistors (including a first N-transistor PD1, a second N-transistor PD2, a third N-transistor PG1, a fourth N-transistor PG2, a fifth N-transistor RP PG, and a sixth N-transistor RP PD); P-type lightly doped drain (P LDD) processes are performed simultaneously for two P-transistors (a first P transistor PU1, and a second P transistor PU2); and then in an external logic area, the following are performed for logic devices: a high V threshold (HVT) N-type lightly doped drain (N LDD) process/an HVT P LDD process/a low V threshold (LVT) N LDD process/an LVT P LDD process/a standard V threshold (SVT) N LDD process/a SVT P LDD/an ultra high V threshold (UHVT) N LDD process/an UHVT P LDD process/an ultra low V threshold (ULVT) N LDD process/an ULVT P LDD process.

A lower threshold voltage enables good speed performance due to a small saturation current. However, power consumption deteriorates because a leakage current becomes large. The speeds for ULVT, LVT, SVT, HVT, and UHVT are in a descending order, while the power consumptions for ULVT, LVT, SVT, HVT, and UHVT are in a reverse order.

A logic device in a logic area using an ULVT LDD process has the highest doping concentration, the smallest threshold voltage and saturation current, the highest speed performance, and the largest leakage current, and leakage power consumption.

For the conventional 8-transistor 2-port static random access memory (8T2P SRAM), in a planar transistor process, respective P-type field effect transistors (Cell PFET device) in a storage unit share a P-type lightly doped drain mask (Cell P LDD mask) of a storage unit to adjust a threshold voltage Vt; respective N-type field effect transistors (Cell PFET device) in a storage unit share a N-type lightly doped drain mask (Cell N LDD mask) of a storage unit to adjust a threshold voltage Vt and its breakthrough current Ids; because respective N-type field effect transistors (Cell PFET device) of the storage unit only use the N-type lightly doped drain mask (Cell N LDD mask) of the storage unit, the electrical properties of 2 external N-type field effect transistors as a read port (the fifth N-transistor RP PG and the sixth N-transistor RP PD) should matched with that of the 2 internal N-type transistors (the second N-transistor PD2 and the fourth N-transistor PG2); and in order for the read/write balance of SRAM, a leakage current cannot be too large, and a speed cannot be too slow, so, the threshold voltage Vt and breakthrough current Ids of 6 transistors (6T Device) inside the SRAM storage unit are specially adjusted to a certain level, and an operation speed of a read port is limited. The results corresponding to breakthrough currents Ids (Cell N/PFET IDS) of respective N-/P-type field-effect transistors of a storage unit are shown in FIG. 4.

### BRIEF SUMMARY

The method for making an 8-transistor 2-port static random access memory, including the following steps:
S1. firstly, simultaneously performing N LDD processes for a first N transistor PD1, a second N transistor PD2, a third N transistor PG1, and a fourth N transistor PG2 in a chip memory area;
S2. secondly, simultaneously performing P LDD processes for a first P transistor PU1 and a second P transistor PU2 in the chip memory area; and
S3. finally, while performing an LDD process for a logic device in a chip logic area, selecting an ion injection mask for an NFET logic device and opening source and drain areas of a fifth N transistor RP PG and a sixth N transistor RP PD for ion injection, so as to complete an N LDD process for the fifth N transistor RP PG and sixth N transistor RP PD.

In some examples, in step S3, the ion implantation mask is the one for an HVT N LDD process, an LVT N LDD process, an SVT N LDD process, an UHVT N LDD process, or an ULVT N LDD process for an NFET in the chip logic area.

In some examples, in step S3, the ion implantation mask is the one for an LVT N LDD process, an SVT N LDD process, or an ULVT N LDD process for the NFET in the chip logic area.

In some examples, in step S3, the ion implantation mask is the one for an HVT N LDD process, an UHVT N LDD process, or an SVT N LDD process for the NFET in the chip logic area.

In some examples, the 8-transistor 2-port static random access memory comprises a first N transistor PD1, a second N transistor PD2, a third N transistor PG1, a fourth N transistor PG2, a first P transistor PU1, a second P transistor PU2, a fifth N transistor RP PG, and a sixth N transistor RP PD;
the source terminals of the first P transistor PU1 and the second P transistor PU2 are connected to an operating voltage Vdd;
the gate terminal of the first P transistor PU1, the drain terminal of the second P transistor PU2, the gate terminal of the first N transistor PD1, the drain terminal of the second N transistor PD2, and the gate terminal of the fifth N transistor RP PG are connected to a second node n2;
the gate terminal of the second P transistor PU2, the drain terminal of the first P transistor PU1, the gate terminal of the second N transistor PD2, and the drain terminal of the first N transistor PD1 are connected to a first node n1;
the gate terminals of the third N transistor PG1 and the fourth N transistor PG2 are connected to an A word line A-WL;
the source and drain of the third N transistor PG1 are connected to the first node n1 and a first bit line BL1, respectively;
the source and drain of the fourth N transistor PG2 are connected to the second node n2 and a second bit line BL2, respectively;
the fifth N transistor RP PG has a gate terminal connected to an B word line B-WL, and a source and a drain connected to the drain terminal of the sixth N transistor RP PD and the B port bit line B-BL, respectively;
the source terminal of the first N transistor PD1, the source terminal of the second N transistor PD2 and the source terminal of the sixth N transistor RP PD are connected to common ground Vss;
the A word line A-WL, the first bit line BL1 and the second bit line BL2 belong to an A port;
the B word line B-WL and the B port bit line belong to a B port; and
the first N-transistor PD1, the second N-transistor PD2, the third N-transistor PG1, the fourth N-transistor PG2, the first P-transistor PU1, and the second P-transistor PU2 are provided in a memory area.

In some examples, the fifth N transistor RP PG and the sixth N transistor RP PD are provided within the memory area or an external logic area.

In some examples, the fifth N transistor RP PG and the sixth N transistor RP PD are JFETs or MOSFETs.

In some examples, the first P transistor PU1 and the second P transistor PU2 are PMOS transistors; and
the first N transistor PD1, the second N transistor PD2, the third N transistor PG1, and the fourth N transistor PG2 are NMOS transistors.

In some examples, in the chip planar layout structure of the 8-transistor 2-port static random access memory:
the first P transistor PU1 is to the left of the second P transistor PU2;
the first N transistor PD1 and the third N transistor PG1 are to the left of the first P transistor PU1, and the first P transistor PU1 is in the front of the third N transistor PG1;
the second N transistor PD2 and the fourth N transistor PG2 are to the right of the second P transistor PU2, and the second N transistor PD2 is behind the fourth N transistor PG2; and
the fifth N transistor RP PG and the sixth N transistor RP PD are to the right of the second N transistor PD2 and the fourth N transistor PG2, and the sixth N transistor RP PD is behind the fifth N transistor RP PG.

In some examples, the left-right-direction center lines of gate polysilicon of the first P transistor PU1, the first N transistor PD1, the fourth N transistor PG2 and the fifth N transistor RP PG are in the same straight line; and
left-right-direction center lines of gate polysilicon of the second P transistor PU2, the third N transistor PG1, the second N transistor PD2 and the sixth N transistor RP PD are on the same straight line.

In the method for making the 8-transistor 2-port static random access memory (8T2P SRAM) of the present application, a lightly doped drain (N LDD) process for 6 transistors (the first N transistor PD1, second N transistor PD2, third N transistor PG1, fourth N transistor PG2, first P transistor PU1, and second P transistor PU2) in a chip memory area uses a N-type lightly doped drain mask (cell N LDD mask) PG PD and a P-type lightly doped drain mask (cell P LDD mask) PU of an original storage unit, the fifth N transistor RP PG and the sixth N transistor RP PD of the B port (read port) are separated from the N-type lightly doped drain mask (cell N LDD mask) of the original storage unit, and the N-type lightly doped drain mask (cell N LDD mask) PG PD of the original storage unit is not used for N ion injection; instead, a logic device NFET Vt mask is used, one of ion implantation masks of N Rvt/N Lvt/N Hvt/N uHvt/N uLvtt is selected when a lightly doped drain process (LDD) is performed for a logic device in a chip logic area, the source and drain areas of the fifth N transistor RP PG and the sixth N transistor RP PD are opened for ion implantation to complete the N-type lightly doped drain (N LDD) process for the fifth N transistor RP PG and the sixth N transistor RP PD to adjust the threshold voltage Vt and source-drain breakthrough current Ids of the fifth N transistor RP PG and the sixth N transistor RP PD, so that the read current Iread and the read speed of the B port (a read port) can be adjusted, as shown in FIG. 6. This method does not affect the read/write balance for 6T SRAM inside a storage unit; the storage unit remains internally stable without an extra mask or an increase in process steps, and thus the process complexity is not affected without new sites.

### BRIEF DESCRIPTION OF THE DRAWINGS

To more clearly illustrate the technical solution of the present application, the figure used in the present application is briefly introduced below. Obviously, the figures in the following description are only some embodiments of the present application, and other figures can be obtained from these figures for those of ordinary skill in the art, without the exercise of inventive effect.

FIG. 1 is an exemplary 8T2P SRAM circuit;

FIG. 2 is a layout diagram of an exemplary 8T2P SRAM;

FIG. 3 is a schematic diagram of opening a mask for an existing process for an 8T2P SRAM;

FIG. 4 is a diagram corresponding to source/drain currents of NMOS/PMOS of a storage unit of an exemplary 8T2P SRAM;

FIG. 5 is a schematic diagram of opening a mask for an example of a method for making an 8T2P SRAM of the present application;

FIG. 6 shows different source/drain currents IDS and corresponding leakage currents (Leakage) for an example of a method for making an 8T2P SRAM of the present application.

### DETAILED DESCRIPTION OF THE DISCLOSURE

The technical solutions in the embodiments of the present application may be described clearly below in conjunction with the figures in the embodiments. Obviously, the described embodiments are only some of the embodiments of the application. The scope of protection of the present application encompasses all other embodiments obtained by those of ordinary skill in the art based on the embodiments of the application without the exercise of inventive effort.

Terms such as “first”, “second”, etc. in the present application do not indicate any order, number, or importance, but are only to distinguish different parts. The phasing “including”, “comprising”, etc. means that the element or object preceded by the phasing encompasses the element or object and equivalents thereof listed below the phasing, but does not exclude other elements or objects. The expression such as “connected”, “coupled”, etc. is not limited to physical or mechanical connections, but may include direct or indirect electrical connections. “Upper”, “lower”, “left”, “right”, etc. are used only to indicate relative positional relations. When an absolute position of a described object is changed, the relative positional relations may also be changed accordingly.

It should be noted that the embodiments of the present application and the features thereof may be combined with each other without contradictory.

### Example I

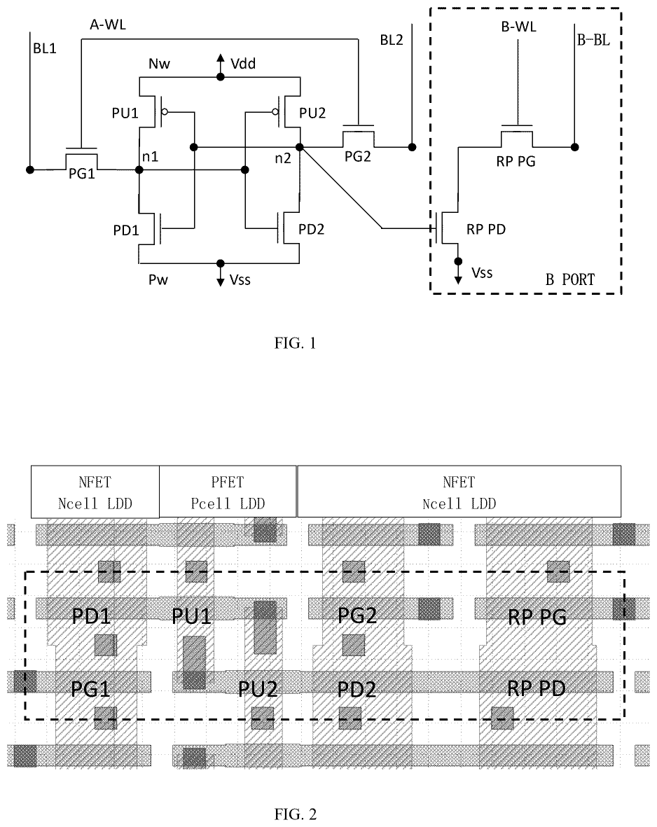

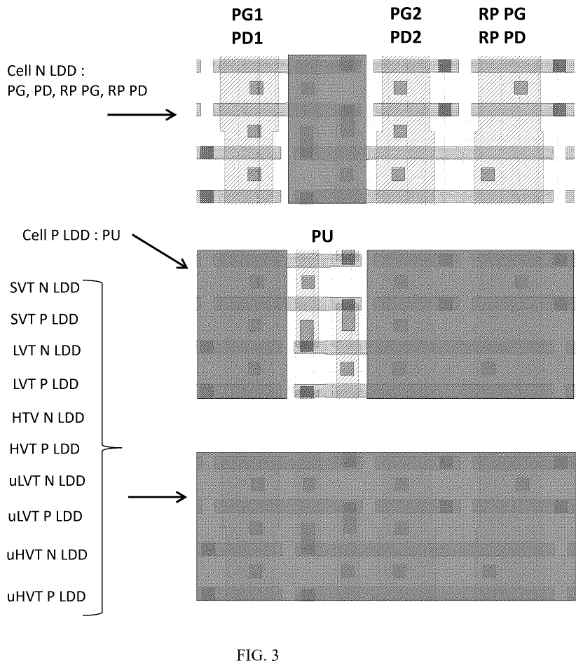

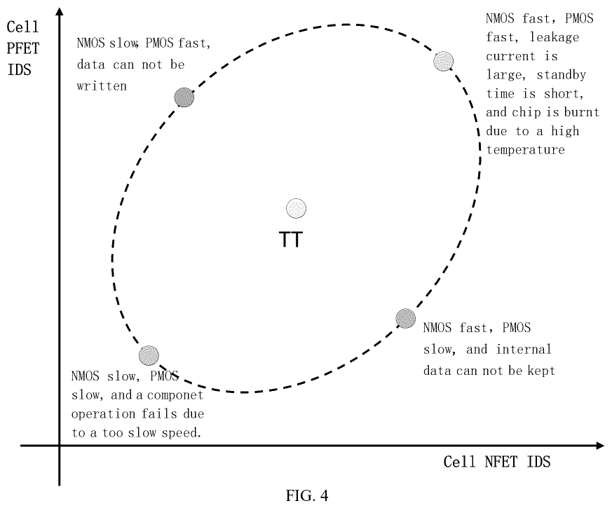

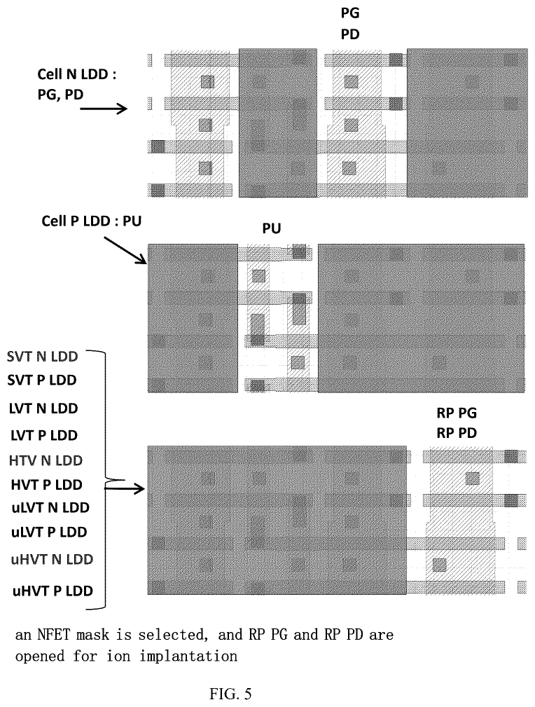

A method for making an 8-transistor 2-port static random access memory (8T2P SRAM) is provided. Referring to FIG. 1, the 8-transistor 2-port static random access memory (8T2P SRAM) includes a first N transistor PD1, a second N transistor PD2, a third N transistor PG1, a fourth N transistor PG2, a first P transistor PU1, a second P transistor PU2, a fifth N transistor RP PG, and a sixth N transistor RP PD;
the source terminals of the first P transistor PU1 and the second P transistor PU2 are connected to an operating voltage Vdd;
the gate terminal of the first P transistor PU1, the drain terminal of the second P transistor PU2, the gate terminal of the first N transistor PD1, the drain terminal of the second N transistor PD2, and the gate terminal of the fifth N transistor RP PG are connected to a second node n2;
the gate terminal of the second P transistor PU2, the drain terminal of the first P transistor PU1, the gate terminal of the second N transistor PD2, and the drain terminal of the first N transistor PD1 are connected to a first node n1;
the gate terminals of the third N transistor PG1 and the fourth N transistor PG2 are connected to an A word line A-WL;
the source and drain of the third N transistor PG1 are connected to the first node n1 and a first bit line BL1, respectively;
the source and drain of the fourth N transistor PG2 are connected to the second node n2 and a second bit line BL2, respectively;
the fifth N transistor RP PG has a gate terminal connected to an B word line B-WL, and a source and a drain connected to the drain terminal of the sixth N transistor RP PD and the B port bit line B-BL, respectively;
the source terminal of the first N transistor PD1, the source terminal of the second N transistor PD2 and the source terminal of the sixth N transistor RP PD are connected to common ground Vss;
the A word line A-WL, the first bit line BL1 and the second bit line BL2 belong to an A port; the A-port is a 6-transistor single port (6T single port), which may have writing and read functions, with a relatively small operation speed;
the B word line B-WL and the B port bit line belong to a B port; the B port is a single port that can be read at a relatively high speed, and is a read port consisting of two N-type transistors; and
the first N transistor PD1, the second N transistor PD2, the third N transistor PG1, the fourth N transistor PG2, the first P transistor PU1, and the second P transistor PU2 are provided in the memory area.

The making method thereof is shown in FIG. 5, including the following steps:
S1. firstly, simultaneously performing N LDD processes for a first N transistor PD1, a second N transistor PD2, a third N transistor PG1, and a fourth N transistor PG2 in a chip memory area;
S2. secondly, simultaneously performing P LDD processes for a first P transistor PU1 and a second P transistor PU2 in the chip memory area; and
S3. finally, while performing an LDD process for a logic device in a chip logic area, selecting an ion injection mask for an NFET logic device and opening source and drain areas of a fifth N transistor RP PG and a sixth N transistor RP PD for ion injection, so as to complete an N LDD process for the fifth N transistor RP PG and sixth N transistor RP PD

Preferably, in step S3, the ion implantation mask is the one, for an NFET (N-type field effect transistor) in the chip logic area, for an HVT (high V threshold) N-type lightly doped drain (N LDD) process, an LVT (low V threshold) N LDD process, an SVT (Standard V threshold) N-type lightly doped drain (N LDD) process, an UHVT (Ultra high V threshold) N-type lightly doped drain (N LDD) process or an ULVT (Ultra low V threshold) N-type lightly doped drain (N LDD) process.

Preferably, in step S3, the ion implantation mask is the one, for an NFET in the chip logic area, for an LVT (Low V threshold) N-type lightly doped drain (N LDD) process, an SVT (Standard V threshold) N-type lightly doped drain (N LDD) process, or an ULVT (Ultra Low V threshold) N-type lightly doped drain (N LDD) process. This process is suitable for 8-transistor 2-port static random access memory (8T2P SRAM) chips that require relatively high speeds and can tolerate relatively high leakage currents (Leakage).

Preferably, in step S3, the ion implantation mask is the one, for the NFET (N-type field effect transistor) in the chip logic area, for an HVT (high V threshold) N-type lightly doped drain (N LDD) process, an UHVT (Ultra high V threshold) N-type lightly doped drain (N LDD) process, or an SVT (Standard V threshold) N-type lightly doped drain (N LDD) process. This process is suitable for 8-transistor 2-port static random access memory (8T2P SRAM) chips that require relatively low power consumption and can tolerate relatively low operating speeds.

Preferably, the fifth N transistor RP PG and the sixth N transistor RP PD are provided within the memory area or an external logic area.

Preferably, the fifth N transistor RP PG and the sixth N transistor RP PD are JFETs or MOSFETs.

Preferably, the first P transistor PU1 and the second P transistor PU2 are PMOS transistors; and
the first N transistor PD1, the second N transistor PD2, the third N transistor PG1, and the fourth N transistor PG2 are NMOS transistors.

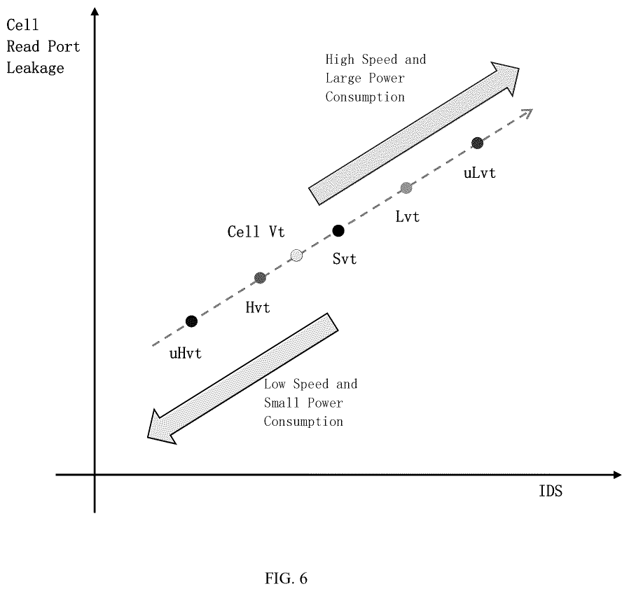

According to the electrical properties of the fifth N transistor RP PG and the sixth N transistor RP PD of the 8-transistor 2-port static random access memory (8T2P SRAM), the threshold voltage Vt and the source-drain breakthrough current Ids of the fifth N transistor RP PG and the sixth N transistor RP PD do not affect the read/write balance during data operations inside a storage unit. The threshold voltage Vt and the source-drain breakthrough current Ids of the planar transistor component can be adjusted by ion implantation, and thus, in the method for making the 8-transistor 2-port static random access memory (8T2P SRAM) in example I, a lightly doped drain (N LDD) process for 6 transistors (the first N transistor PD1, second N transistor PD2, third N transistor PG1, fourth N transistor PG2, first P transistor PU1, and second P transistor PU2) in a chip memory area uses a N-type lightly doped drain mask (cell N LDD mask) PG PD and a P-type lightly doped drain mask (cell P LDD mask) PU of an original storage unit, the fifth N transistor RP PG and the sixth N transistor RP PD of the B port (read port) are separated from the N-type lightly doped drain mask (cell N LDD mask) of the original storage unit, and the N-type lightly doped drain mask (cell N LDD mask) PG PD of the original storage unit is not used for N ion injection; instead, a logic device NFET Vt mask is used, one of ion implantation masks of N Rvt/N Lvt/N Hvt/N uHvt/N uLvtt is selected when a lightly doped drain process (LDD) is performed for a logic device in a chip logic area, the source and drain areas of the fifth N transistor RP PG and the sixth N transistor RP PD are opened for ion implantation to complete the N-type lightly doped drain (N LDD) process for the fifth N transistor RP PG and the sixth N transistor RP PD to adjust the threshold voltage Vt and source-drain breakthrough current Ids of the fifth N transistor RP PG and the sixth N transistor RP PD, so that the read current Iread and the read speed of the B port (a read port) can be adjusted, as shown in FIG. 6. This method does not affect the read/write balance for 6T SRAM inside a storage unit; the storage unit remains internally stable without an extra mask or an increase in process steps, and thus the process complexity is not affected without new sites.

### Example 2

Based on the method for making the 8-transistor 2-port static random access memory (8T2P SRAM) of Example 1, the chip planar layout structure of the 8-transistor 2-port static random access memory (8T2P SRAM) is shown in FIG. 5:
the first P transistor PU1 is to the left of the second P transistor PU2;
the first N transistor PD1 and the third N transistor PG1 are to the left of the first P transistor PU1, and the first P transistor PU1 is in the front of the third N transistor PG1;
the second N transistor PD2 and the fourth N transistor PG2 are to the right of the second P transistor PU2, and the second N transistor PD2 is behind the fourth N transistor PG2; and
the fifth N transistor RP PG and the sixth N transistor RP PD are to the right of the second N transistor PD2 and the fourth N transistor PG2, and the sixth N transistor RP PD is behind the fifth N transistor RP PG.

Preferably, the left-right-direction center lines of gate polysilicon of the first P transistor PU1, the first N transistor PD1, the fourth N transistor PG2 and the fifth N transistor RP PG are in the same straight line; and
left-right-direction center lines of gate polysilicon of the second P transistor PU2, the third N transistor PG1, the second N transistor PD2 and the sixth N transistor RP PD are on the same straight line.

The embodiments described above are only preferred embodiments of the present application and are not intended to limit the present application. The scope of protection of the application shall include any modifications, equivalent substitutions, improvements, etc. made within the spirit and principles of the present application.

What is claimed is:

1. A method for making an 8-transistor 2-port static random access memory, comprising the following steps:
S1. firstly, simultaneously performing N LDD processes for a first N transistor (PD1), a second N transistor (PD2), a third N transistor (PG1), and a fourth N transistor (PG2) in a chip memory area;
S2. secondly, simultaneously performing P LDD processes for a first P transistor (PU1) and a second P transistor (PU2) in the chip memory area; and
S3. finally, while performing an LDD process for a logic device in a chip logic area, selecting an ion injection mask for an NFET logic device and opening source and drain areas of a fifth N transistor (RP PG) and a sixth N transistor (RP PD) for ion injection, so as to complete an N LDD process for the fifth N transistor (RP PG) and sixth N transistor (RP PD).

2. The method for making an 8-transistor 2-port static random access memory according to claim 1, wherein in step S3, the ion implantation mask is the one for an HVT N LDD process, an LVT N LDD process, an SVT N LDD process, an UHVT N LDD process, or an ULVT N LDD process for an NFET in the chip logic area.

3. The method for making an 8-transistor 2-port static random access memory according to claim 1, wherein in step S3, the ion implantation mask is the one for an LVT N LDD process, an SVT N LDD process, or an ULVT N LDD process for the NFET in the chip logic area.

4. The method for making an 8-transistor 2-port static random access memory according to claim 1, wherein in step S3, the ion implantation mask is the one for an HVT N LDD process, an UHVT N LDD process, or an SVT N LDD process for the NFET in the chip logic area.

5. The method for making an 8-transistor 2-port static random access memory according to claim 1, wherein
the 8-transistor 2-port static random access memory comprises a first N transistor (PD1), a second N transistor (PD2), a third N transistor (PG1), a fourth N transistor (PG2), a first P transistor (PU1), a second P transistor (PU2), a fifth N transistor (RP PG), and a sixth N transistor (RP PD);
the source terminals of the first P transistor (PU1) and the second P transistor (PU2) are connected to an operating voltage (Vdd);
the gate terminal of the first P transistor (PU1), the drain terminal of the second P transistor (PU2), the gate terminal of the first N transistor (PD1), the drain terminal of the second N transistor (PD2), and the gate terminal of the fifth N transistor (RP PG) are connected to a second node (n2);
the gate terminal of the second P transistor (PU2), the drain terminal of the first P transistor (PU1), the gate terminal of the second N transistor (PD2), and the drain terminal of the first N transistor (PD1) are connected to a first node (n1);
the gate terminals of the third N transistor (PG1) and the fourth N transistor (PG2) are connected to an A word line (A-WL);
the source and drain of the third N transistor (PG1) are connected to the first node (n1) and a first bit line (BL1), respectively;
the source and drain of the fourth N transistor (PG2) are connected to the second node (n2) and a second bit line (BL2), respectively;
the fifth N transistor (RP PG) has a gate terminal connected to an B word line (B-WL), and a source and a drain connected to the drain terminal of the sixth N transistor (RP PD) and the B port bit line (B-BL), respectively;
the source terminal of the first N transistor (PD1), the source terminal of the second N transistor (PD2) and the source terminal of the sixth N transistor (RP PD) are connected to common ground (Vss);
the A word line (A-WL), the first bit line (BL1) and the second bit line (BL2) belong to an A port;
the B word line (B-WL) and the B port bit line belong to a B port; and
the first N-transistor (PD1), the second N-transistor (PD2), the third N-transistor (PG1), the fourth N-transistor (PG2), the first P-transistor (PU1), and the second P-transistor (PU2) are provided in a memory area.

6. The method for making an 8-transistor 2-port static random access memory according to claim 5, wherein the fifth N transistor (RP PG) and the sixth N transistor (RP PD) are provided within the memory area or an external logic area.

7. The method for making an 8-transistor 2-port static random access memory according to claim 5, wherein the fifth N transistor (RP PG) and the sixth N transistor (RP PD) are JFETs or MOSFETs.

8. The method for making an 8-transistor 2-port static random access memory according to claim 5, wherein
the first P transistor (PU1) and the second P transistor (PU2) are PMOS transistors; and
the first N transistor (PD1), the second N transistor (PD2), the third N transistor (PG1) and the fourth N transistor (PG2) are NMOS transistors.

9. The method for making an 8-transistor 2-port static random access memory according to claim 1, wherein
in the chip planar layout structure of the 8-transistor 2-port static random access memory,
the first P transistor (PU1) is to the left of the second P transistor (PU2);
the first N transistor (PD1) and the third N transistor (PG1) are to the left of the first P transistor (PU1), and the first P transistor (PU1) is in the front of the third N transistor (PG1);
the second N transistor (PD2) and the fourth N transistor (PG2) are to the right of the second P transistor (PU2), and the second N transistor (PD2) is behind the fourth N transistor (PG2); and
the fifth N transistor (RP PG) and the sixth N transistor (RP PD) are to the right of the second N transistor (PD2) and the fourth N transistor (PG2), and the sixth N transistor (RP PD) is behind the fifth N transistor (RP PG).

10. The method for making an 8-transistor 2-port static random access memory according to claim 9, wherein
left-right-direction center lines of gate polysilicon of the first P transistor (PU1), the first N transistor (PD1), the fourth N transistor (PG2) and the fifth N transistor (RP PG) are in the same straight line; and
left-right-direction center lines of gate polysilicon of the second P transistor (PU2), the third N transistor (PG1), the second N transistor (PD2) and the sixth N transistor (RP PD) are on the same straight line.
